(19) United States
(12) Patent Application Publication
(10) Pub. No.: US 2001/0013614 A1
(43) Pub. Date: Aug. 16, 2001

(54) Iridium oxide diffusion barrier between local interconnect layer and thin film of layered superlattice material

(76) Inventors: Vikram Joshi, Colorado Springs, CO (US); Joseph D. Cuchiaro, Colorado Springs, CO (US); Carlos A. Paz de Araujo, Colorado Springs, CO (US)

Correspondence Address: PATTON BOGGS, PO BOX 270930, LOUISVILLE, CO, 80027, US

(21) Appl. No.: 09/769,216

(22) Filed: Jan. 24, 2001

Related U.S. Application Data
(62) Division of application No. 09/250,616, filed on Feb. 16, 1999, now abandoned.

(51) Int. Cl. H01L 21/00; H01L 29/76; H01L 29/94; H01L 31/062; H01L 31/113; H01L 31/119

(52) U.S. Cl. 257/295; 438/3

(57) ABSTRACT

A diffusion barrier layer in an integrated circuit is located to inhibit undesired diffusion of chemical species from local interconnects into layered superlattice material in a thin film memory capacitor. The diffusion barrier layer comprises iridium oxide. The thin film of layered superlattice material is ferroelectric or nonferroelectric, high-dielectric constant material. Preferably, the thin film comprises ferroelectric layered superlattice material. The diffusion barrier layer is located between a local interconnect and the memory capacitor. Preferably, the diffusion barrier layer is in direct contact with the local interconnect. The iridium-oxide diffusion barrier is effective for preventing diffusion of metals, silicon and other chemical species.

### BACKGROUND OF THE INVENTION

1. Field of the Invention

The invention relates to a composition of material used in an integrated circuit that protects electronic properties of memory capacitors by inhibiting diffusion of metals from local interconnects into layered superlattice material oxides.

2. Statement of the Problem

Layered superlattice materials contained in memory capacitors of a nonvolatile, ferroelectric random access memory cell (“FeRAM”) are metal-oxide compounds. A ferroelectric capacitor is useful in a nonvolatile memory cell when it possesses desired electronic characteristics, such as high residual polarization, good coercive field, high fatigue resistance, and low leakage current. Layered superlattice material oxides possess favorable characteristics for use in nonvolatile integrated circuit memories. See Watanabe, U.S. Pat. No. 5,434,102. Certain nonferroelectric layered superlattice materials are useful in dynamic random access memory (“DRAM”) cells because they exhibit high dielectric constants.

A typical memory in an integrated circuit contains a semiconductor substrate and a metal-oxide semiconductor field-effect transistor (MOSFET) in electrical contact with a ferroelectric or dielectric device, usually a capacitor. A memory capacitor typically contains a thin film of ferroelectric or dielectric material located between a first or bottom electrode and a second or top electrode, the electrodes typically containing platinum.

The most common scheme of local interconnect (“LI”) metallization in FeRAM and DRAM cells contains titanium or titanium nitride or both. The electrodes of the memory capacitors typically are platinum metal. During backend processes after formation of the LI, titanium (“Ti”) diffuses through the platinum, or other metal, electrode into the thin film of capacitor dielectric, where it displaces certain atoms, for example, tantalum, niobium and zirconium, from their sites in the crystal lattice. The substitution of titanium atoms into the metal-oxide crystal structure degrades the electronic properties of the capacitor. This problem is acute in memories containing layered superlattice material compounds because these oxide compounds are particularly complex and prone to degradation by titanium.

A LI layer typically contains other chemical species besides titanium that are capable of diffusing through platinum electrode layers or other types of electrode layers, causing damage to the layered superlattice material. Examples of such other chemical species are: aluminum, copper, titanium, titanium nitride and tungsten. Tungsten and polycrystalline silicon are typically contained in LI plugs providing electrical contact between a MOSFET and a memory capacitor. Tungsten and silicon are able to diffuse through an electrode and damage layered superlattice material.

Integrated circuit devices containing thin films of layered superlattice materials are currently being manufactured. Nevertheless, the problem of diffusion of titanium and other chemical species out of the LI layers into the layered superlattice material, and the resulting degradation of electronic properties during the manufacturing process, hinders the economical production in commercial quantities of FeRAMs, DRAMs, and other IC devices of good quality using the layered superlattice material compounds. There is a need for barrier material that can be incorporated into the integrated circuit between the thin film of layered superlattice material and the LI to prevent diffusion of titanium and other chemical species into the layered superlattice material. The barrier material must remain a good electrical conductor, as well as a diffusion barrier, at the moderately high temperatures, for example, at 500° C., at which some backend manufacturing processes are conducted.

In a study by Nakamura et. al., reported in Jpn. J. of Appl. Phys., Vol. 33, 5207-5210 (1994), a 50 nm-thick layer of iridium oxide was used as part of both the bottom and top platinum electrodes in capacitors having a thin film of PZT. The 2Pr-value of about 33 μC/cm² showed virtually no change due to fatigue after 10¹² bipolar pulses at 5 volts. In PZT capacitors with Pt/Ti electrodes and no iridium or iridium oxide, the 2Pr-value was initially less at about 25 μC/cm², and it decreased about 50% after 10⁸ cycles; but the iridium oxide was not disclosed as a barrier to protect layered superlattice material or to inhibit diffusion of chemical species from a local interconnect into the dielectric thin film of a capacitor.

U.S. Pat. No. 5,773,315, issued Jun. 30, 1998 to Jiang et. al., discloses a barrier region and a bottom electrode comprising iridium oxide to protect tungsten plugs by functioning as barriers to oxygen; however, in this reference, the iridium oxide is not disclosed as a barrier to metal diffusion into the dielectric layer of a capacitor.

3. Solution to the Problem

The invention solves the problems discussed above by disclosing a novel composition of material for use as a diffusion barrier to protect layered superlattice material. The inventive composition is iridium oxide (“IrO₂”).

A feature of the invention is an integrated circuit in which a diffusion barrier layer comprising iridium oxide is located to inhibit diffusion of titanium and other chemical species towards a thin film of layered superlattice material. The inventive diffusion barrier layer is located between a local interconnect and the thin film of layered superlattice material. Preferably, the diffusion barrier layer is in direct contact with the local interconnect.

In a typical embodiment of the invention, the local interconnect is a metallized wiring layer, and the thin film of layered superlattice material is a dielectric thin film in a memory capacitor. Typically, a metal top electrode layer of a memory capacitor is formed on the dielectric thin film of layered superlattice material, and then the diffusion barrier layer is located on the top electrode layer. The metallized layer is located above the diffusion barrier layer, preferably in direct contact with the diffusion barrier layer. The metallized wiring layer typically contains aluminum, titanium, titanium nitride, copper and tungsten, as well as other metals. The diffusion barrier layer inhibits the diffusion of such metals from the metallized wiring layer towards the dielectric thin film.

In another embodiment of the invention, the local interconnect is an electrically conductive plug that serves to connect a MOSFET of a memory cell to the memory capacitor. The memory capacitor has a bottom electrode, and the diffusion barrier layer is located under the bottom electrode and above the conductive plug. Preferably, the diffusion barrier layer is in direct contact with the plug. The conductive plug typically comprises chemical species including polycrystalline silicon or tungsten, and the diffusion barrier layer inhibits diffusion of the chemical species from the conductive plug towards the dielectric thin film of the memory capacitor.

Preferably, the layered superlattice material is a ferroelectric layered superlattice material. For example, layered superlattice material comprising strontium, bismuth and tantalum (“strontium bismuth tantalate” or “SBT”) is an effective dielectric thin film in a FeRAM; SBT having a chemical formula SrBi₂Ta₂O₉ is widely used by those skilled in the art. Another effective ferroelectric layered superlattice material contains strontium, bismuth, tantalum and niobium (“strontium bismuth tantalum niobate” or “SBTN”); SBTN having a chemical formula SrBi_{2.18}(Ta₁₋ₓNbₓ)O₉, where 0<x<1, is widely used in the art. The layered superlattice material may also be nonferroelectric, high-dielectric constant material.

Another feature of the invention is a method of forming an integrated circuit. In one basic embodiment, the method comprises steps of: forming a thin film of layered superlattice material; forming a local interconnect; and forming a diffusion barrier layer, the diffusion barrier layer comprising iridium oxide and located between the thin film of layered superlattice material and the local interconnect. Typically, the local interconnect is formed as a metallized wiring layer; and the thin film of layered superlattice material is formed as a dielectric thin film in a memory capacitor. The method may further comprise a step of forming a top electrode layer on the dielectric thin film, wherein the diffusion barrier layer is formed on the top electrode layer, and the metallized wiring layer is formed on the diffusion barrier layer.

In another basic embodiment, the local interconnect is formed as an electrically conductive plug, and the thin film of layered superlattice material is formed as a dielectric thin film in a memory capacitor. Typically, the diffusion barrier layer is formed above the electrically conductive plug, a bottom electrode layer is formed on the diffusion barrier layer, and then the thin film of layered superlattice material is formed on the bottom electrode layer.

Numerous other features, objects and advantages of the invention will become apparent from the following description when read in conjunction with the accompanying drawings.

### BRIEF DESCRIPTION OF THE DRAWINGS

FIG. 1 is a cross-sectional view of a portion of an integrated circuit showing a memory cell in which the memory capacitor is displaced laterally from the switch, and a diffusion barrier layer comprising iridium oxide has been patterned with the top electrode layer of the capacitor;

FIG. 2 is a cross-sectional view of a portion of an integrated circuit showing a memory capacitor in which a diffusion barrier layer comprising iridium oxide has been formed in the wiring hole at the top electrode;

FIG. 3 is a cross-sectional view of another embodiment of the invention, showing a memory cell in which a memory capacitor is stacked substantially above the switch region of the memory cell, and in which diffusion barrier layers comprising iridium oxide are located between the switch region and the overlying region containing the memory capacitor;

FIG. 4 is a flow chart showing the preferred embodiment of a process for fabricating a memory device incorporating a diffusion barrier layer according to the invention, as depicted in FIG. 1;

FIG. 5 is a top view of an exemplary wafer on which thin film capacitors and diffusion barrier layers fabricated in accordance with the invention are shown greatly enlarged;

FIG. 6 is a portion of a cross-section of FIG. 5 taken through the line 6-6, illustrating a thin film capacitor device fabricated in accordance with the invention; and

FIG. 7 is a graph of hysteresis curves measured at 3 volts, in which polarization, μC/cm², is plotted versus annealing temperature, in units of degrees Celsius, in strontium bismuth tantalate thin-film capacitors, to study the effects of diffusion barrier layers comprising iridium oxide, in accordance with the invention.

### DETAILED DESCRIPTION OF THE PREFERRED EMBODIMENT

1. Overview and Description of Integrated Circuit

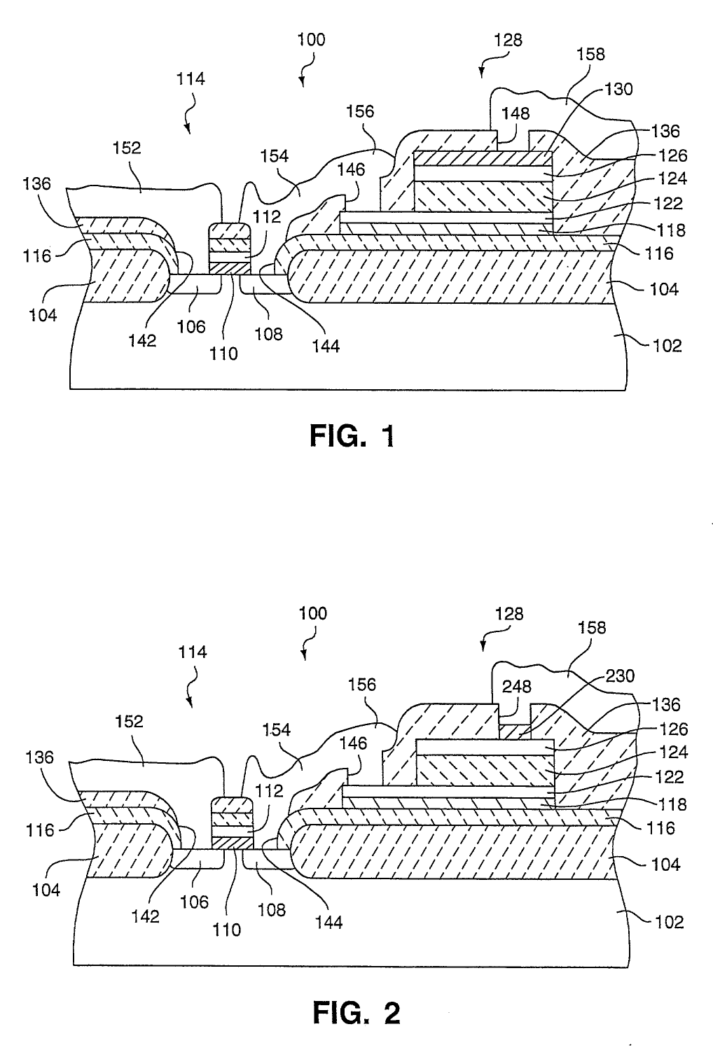

It should be understood that FIGS. 1-3, 5, and 6 depicting ferroelectric integrated circuit devices are not meant to be actual plan or cross-sectional views of any particular portions of actual integrated circuit devices. In actual devices, the layers will not be as regular and the thicknesses may have different proportions. The various layers in actual devices often are curved and possess overlapping edges. The figures instead show idealized representations that are employed to depict more clearly and fully the structure of the invention than would otherwise be possible.

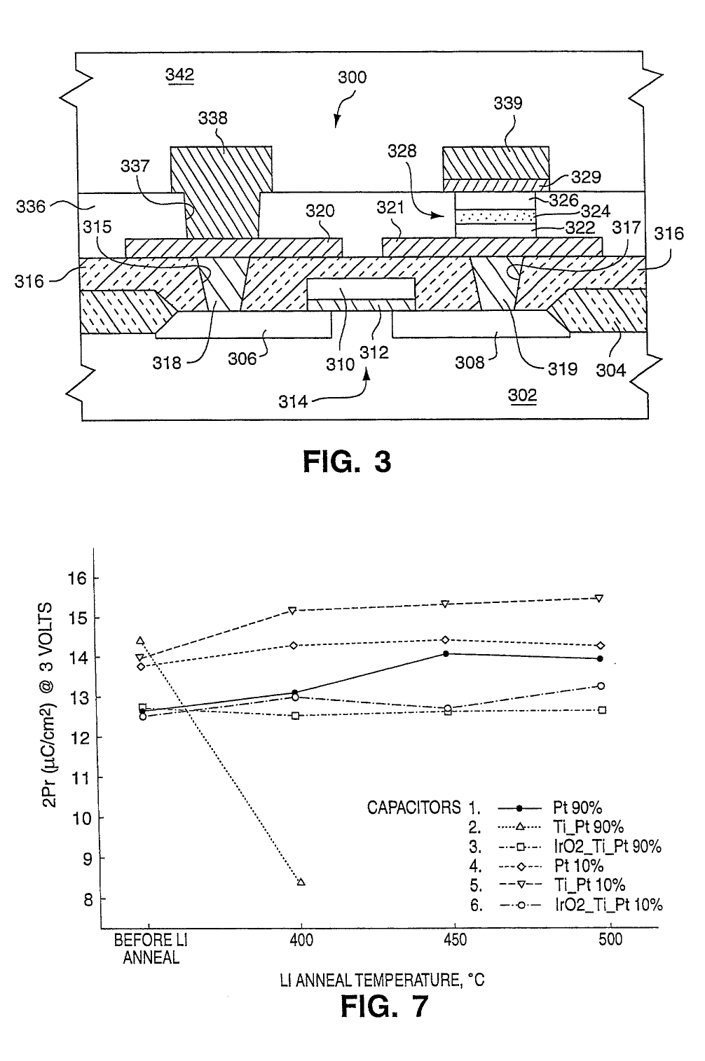

Also, the figures represent only several of innumerable variations of ferroelectric or nonferroelectric, high-dielectric constant devices that could be fabricated using the method of the invention. FIGS. 1-2 depict ferroelectric memories containing a switch in the form of a field effect transistor in electrical connection with a ferroelectric capacitor displaced laterally from the switch. But, as depicted in FIG. 3, it is also contemplated to use the invention in a FeRAM or DRAM containing a stacked capacitor connected via a plug to the switch element below the capacitor. The invention can also be applied in a FET memory in which the ferroelectric element is incorporated in the switch element. Such a ferroelectric FET was described in McMillan, U.S. Pat. No. 5,523,964. Likewise, other integrated circuits fabricated using the unique diffusion barrier layers of the invention could include other elements and compositions of material. For example, although this description of the invention focuses on a diffusion barrier layer used to protect a ferroelectric nonvolatile memory, the invention is useful to protect integrated circuit devices containing nonferroelectric, high-dielectric constant layered superlattice materials against damage caused by diffusion of chemical species contained in local interconnects.

Since ferroelectric material used in integrated circuits also possesses dielectric properties, the term “dielectric” is used in some places of this disclosure to refer generally both to structures or materials having ferroelectric properties and to those with nonferroelectric, high-dielectric constant characteristics. If the meaning is not clear from the context, the broader definition that includes both ferroelectric and nonferroelectric, high-dielectric constant materials should be used.

A material is considered to have a “high” dielectric constant if its dielectric constant is 20 or higher. Where high-dielectric constant materials are used, it is usually preferred that the dielectric constant be 50 or higher.

In FIG. 1, there is shown a cross-sectional view of an exemplary nonvolatile ferroelectric memory cell 100 that could be fabricated according to the invention. The general manufacturing steps for fabricating integrated circuits containing MOSFETs and ferroelectric capacitor elements are described in U.S. Pat. No. 5,466,629 issued Nov. 14, 1995, to Mihara et al., and U.S. Pat. No. 5,468,684 issued Nov. 21, 1995, to Yoshimori et al., which are hereby incorporated by reference as if fully disclosed herein. General fabrication methods have been described in other references also. Therefore, the elements of the circuit of FIG. 1 will be simply identified here. For the sake of clarity, identical elements depicted in FIGS. 1 and 2 are identified with the same reference numerals.

In FIG. 1, a field oxide region 104 is formed on a surface of a silicon substrate 102. A source region 106 and a drain region 108 are formed separately from each other within silicon substrate 102. A gate insulating layer 110 is formed on the silicon substrate 102 between the source and drain regions 106 and 108. Further, a gate electrode 112 is formed on the gate insulating layer 110. These source region 106, drain region 108, gate insulating layer 110 and gate electrode 112 together form a MOSFET 114.

A first interlayer dielectric layer (ILD) 116 made of BPSG (boron-doped phospho-silicate glass) is formed on substrate 102 and field oxide region 104. An adhesion layer 118 is formed on ILD 116. The adhesion layer 118 is made of, for example, titanium, and typically has a thickness of 20 nm. Adhesion layers, such as titanium, enhance the adhesion of the electrodes to adjacent underlying or overlying layers of the circuits.

As depicted in FIG. 1, a bottom electrode layer 122 made of platinum and having a thickness of 200 nm is deposited on adhesion layer 118. The titanium in adhesion layer 118 is typically stabilized by oxidation; therefore, it does not diffuse upwards through bottom electrode layer 122. A dielectric thin film 124 of ferroelectric layered superlattice material is formed on bottom electrode layer 122. A top electrode layer 126, made of platinum and having a thickness of 200 nm, is formed on the thin film 124 of layered superlattice material. Electrode layers 122 and 126 together with thin film 124 of layered superlattice material form memory capacitor 128. The composition of the thin film 124 of layered superlattice material is discussed in more detail below.

An electrically-conductive diffusion barrier layer 130 is deposited on top electrode layer 126. Diffusion barrier layer 130 has a thickness in the range of 20 to 200 nm, preferably in the range of 20 to 50 nm. In accordance with the invention, diffusion barrier layer 130 comprises iridium oxide. Layers 118, 122, 124, 126 and 130 are patterned, in as few as two patterning process steps, to form memory capacitor 128 with self-aligned diffusion barrier layer 130.

A second interlayer dielectric layer (ILD) 136 made of NSG (nondoped silicate glass) is deposited to cover ILD 116, ferroelectric memory capacitor 128 and diffusion barrier layer 130. A PSG (phospho-silicate glass) film or a BPSG film could also be used in layer 136.

ILD 136 is patterned to form wiring holes for electrical contacts to MOSFET 114 and ferroelectric memory capacitor 128. Wiring hole 142 is selectively opened through ILD 136 and ILD 116 to expose the source region 106, and wiring hole 144 is selectively opened through ILD 136 and ILD 116 to expose the gate region 108. Wiring hole 146 is selectively opened through ILD 136 to expose a portion of the bottom electrode 122. Wiring hole 148 is selectively opened through ILD 136 to expose diffusion barrier layer 130.

Source electrode metallized wiring layer 152 (also referred to as local interconnect or LI 152) and drain electrode metallized wiring layer 154 (also referred to as local interconnect or LI 154) are formed to fill wiring holes 142 and 144, respectively. Bottom electrode metallized wiring layer 156 (also referred to as local interconnect or LI 156) and top electrode metallized wiring layer 158 (also referred to as local interconnect or LI 158) are formed to fill wiring holes 146 and 148, respectively. The drain electrode metallized wiring layer 154 is electrically connected to bottom electrode metallized wiring layer 156, and preferably is the same wiring element. Each of these metallized wiring layers 152, 154, 156 and 158 preferably comprises Al—Si—Cu—Ti with a thickness of 200-300 nm.

In an alternative embodiment, as shown in FIG. 2, ILD 136 of memory cell 200 is formed on top electrode layer 126, and a wiring hole 248 is etched through ILD 136 down to top electrode layer 126. Then a diffusion barrier layer 230 is formed in wiring hole 248 prior to forming LI 158.

In a third exemplary embodiment depicted in FIG. 3, a memory capacitor 328 is “stacked” above the switch, namely MOSFET 314, of memory cell 300. A field oxide region 304 is formed on a surface of a silicon substrate 302. A source region 306 and a drain region 308 are formed separately from each other within silicon substrate 302. A gate insulating layer 310 is formed on silicon substrate 304 between the source and drain regions 306 and 308. Further, a gate electrode 312 is formed on the gate insulating layer 310. These source region 306, drain region 308, gate insulating layer 310 and gate electrode 312 together form a MOSFET 314.

A first interlayer dielectric layer (ILD) 316 made of BPSG (boron-doped phospho-silicate glass) is formed on substrate 304 and field oxide region 302. ILD 316 is patterned to form vias 315, 317 to source region 306 and drain region 308, respectively. Vias 315, 317 are filled to form electrically conductive plugs 318, 319, respectively. Conductive plugs 318, 319 typically comprise tungsten or polycrystalline silicon. A layer of iridium oxide is deposited on ILD 316 above plugs 318, 319 and MOSFET 314. The layer of iridium oxide is patterned and etched to form diffusion barrier layer 320 above conductive plug 318 (also referred to as local interconnect or LI 318) and source region 306, and diffusion barrier layer 321 above conductive plug 319 (also referred to as local interconnect or LI 319) and gate region 308. Diffusion barrier layer 320 is in electrical contact with conductive plug 318. Diffusion barrier layer 321 is in electrical contact with conductive plug 319. The diffusion barrier layers typically have a thickness of 20 to 200 nm, preferably 20 to 50 nm.

As depicted in FIG. 3, a bottom electrode layer 322 made of platinum and having a thickness of 200 nm is deposited on diffusion barrier layer 321. Then a dielectric thin film 324 of ferroelectric layered superlattice material is formed on bottom electrode layer 322. Thin film 324 typically has a thickness in the range of 50-300 nm. A top electrode layer 326, made of platinum and having a thickness of 200 nm, is formed on the dielectric thin film 324. Bottom electrode layer 322, dielectric thin film 324 and top electrode layer 326 together form ferroelectric memory capacitor 328. The composition of dielectric thin film 324 is discussed in more detail below. Diffusion barrier layers 320, 321 inhibit the diffusion of chemical species contained in the local interconnects represented by conductive plugs 318, 319 to the region of the ferroelectric memory capacitor 328.

Wafer substrate 102, 302 may comprise silicon, gallium arsenide or other semiconductor, or an insulator, such as silicon dioxide, glass or magnesium oxide (MgO). The bottom and top electrodes of memory capacitors conventionally contain platinum. It is preferable that the bottom electrode contains a non-oxidized precious metal such as platinum, palladium, silver, and gold. In addition to the precious metal, metal such as aluminum, aluminum alloy, aluminum silicon, aluminum nickel, nickel alloy, copper alloy, and aluminum copper may be used for electrodes of a ferroelectric memory. Adhesive layers (not shown), such as titanium, enhance the adhesion of the electrodes to adjacent underlying or overlying layers of the circuits.

A second interlayer dielectric layer (ILD) 336 made of NSG (nondoped silicate glass) is deposited to cover ILD 316, diffusion barrier layers 320, 321, and ferroelectric memory capacitor 328. A PSG (phospho-silicate glass) film or a BPSG (boron phospho-silicate glass) film could also be used in layer 336.

ILD 336 is patterned to form a via 337 to diffusion barrier layer 320. A metallized wiring film is deposited to cover ILD 336 and fill via 337 and then patterned to form plug 337, source electrode metallized wiring layer 338, and top electrode metallized wiring layer 339. Alternatively, a layer of iridium oxide may be deposited, patterned and etched to form diffusion barrier layer 329 before the wiring film is deposited. Metallized wiring layers 338, 339 preferably comprise Al—Si—Cu—Ti standard interconnect metal with a thickness of about 200-300 nm.

The word “substrate” can mean the underlying wafer 102, 302 on which the integrated circuit is formed, as well as any object on which a thin film layer is deposited, such as BPSG layer 116. In this disclosure, “substrate” shall mean the object to which the layer of interest is applied; for example, when we are talking about a bottom electrode, such as 122, the substrate includes the layers 118 and 116 on which the electrode 122 is formed.

Terms of orientation herein, such as “above”, “top”, “upper”, “below”, “bottom”, and “lower” mean relative to the silicon substrate 102. That is, if a second element is “above” a first element, it means it is farther from the substrate 102, and if it is “below” another element then it is closer to the substrate 102 than the other element. The long dimension of substrates 102, 302 defines a plane that is considered to be a “horizontal” plane herein, and directions perpendicular to this plane are considered to be “vertical”.

A memory cell typically comprises a relatively flat thin film of dielectric material. The terms “lateral” or “laterally” refer to the direction of the flat plane of the thin film. In FIG. 1, the lateral direction would be the horizontal direction.

This specification refers to a diffusion barrier layer located between a local interconnect and a thin film of layered superlattice material. The term “between” does not mean that the barrier layer is in direct contact with the thin film of layered superlattice material. Typically, the barrier layer does not contact the thin film of layered superlattice material; but the diffusion barrier layer typically is in direct contact with the local interconnect to prevent diffusion of titanium and other chemical species therefrom into other elements and regions of the integrated circuit. The term “on” is often used in the specification when referring to the deposition or formation of an integrated circuit layer onto an underlying substrate or layer. In contrast to “between”, the term “on” generally signifies direct contact, as is clear in the various contexts in which it is used.

In the preferred embodiment of the invention, as depicted in FIG. 1, the diffusion barrier layer is located above top electrode layer 126, directly over thin film 124 of layered superlattice material. Since the composition of the diffusion barrier layer according to the invention is electrically conductive, the diffusion barrier layer is not in direct contact with the sides of memory capacitor 128.

The term “thin film” is used herein as it is used in the integrated circuit art. Generally, it means a film of less than a micron in thickness. The thin films disclosed herein are in all instances less than 0.5 microns in thickness. Preferably, the iridium-oxide diffusion barrier layers of the invention are in the range of 20-50 nm. Preferably, the dielectric thin films 124, 324 are 50 nm to 300 nm thick, and most preferably 50 to 150 nm thick. These thin films of the integrated circuit art should not be confused with the layered capacitors of the macroscopic capacitor art which are formed by a wholly different process which is incompatible with the integrated circuit art.

The composition of the dielectric thin films 124, 324 can be selected from a group of suitable ferroelectric layered superlattice materials. Alternatively, the thin film 124, 324 may comprise nonferroelectric, high-dielectric constant layered superlattice materials used in DRAM cells

U.S. Pat. No. 5,519,234 issued May 21, 1996, incorporated herein by reference, discloses that layered superlattice compounds, such as strontium bismuth tantalate (SBT), have excellent properties in ferroelectric applications as compared to the best prior materials and have high dielectric constants and low leakage currents. U.S. Pat. Nos. 5,434,102 issued Jul. 18, 1995 and 5,468,684 issued Nov. 21, 1995, incorporated herein by reference, describe processes for integrating these materials into practical integrated circuits. Ferroelectric layered superlattice materials, like the metal oxides SrBi₂Ta₂O₉ (SBT) and SrBi₂(Ta₁₋ₓNbₓ)₂O₉ (SBTN), where 0≦x≦ 1, are currently underdevelopment for use as capacitor dielectrics in nonvolatile memory applications (FeRAM).

The layered superlattice materials may be summarized generally under the formula:

$${A1}_{w1}^{+ a1} {A2}_{w2}^{+ a2} … {Aj}_{wj}^{+ aj} {S1}_{x1}^{+ s1} {S2}_{x2}^{+ s2} … {Sk}_{sk}^{+ sk} {B1}_{y1}^{+ b1} {B2}_{y2}^{+ b2} … {Bl}_{yl}^{+ bl} {Q}_{z}^{- 2} , \qquad ( 1 )$$

where A1, A2 . . . Aj represent A-site elements in the perovskite-like structure, which may be elements such as strontium, calcium, barium, bismuth, lead, and others; S1, S2 . . . Sk represent superlattice generator elements, which usually is bismuth, but can also be materials such as yttrium, scandium, lanthanum, antimony, chromium, thallium, and other elements with a valence of +3; B1, B2 . . . B1 represent B-site elements in the perovskite-like structure, which may be elements such as titanium, tantalum, hafnium, tungsten, niobium, zirconium, and other elements; and Q represents an anion, which generally is oxygen but may also be other elements, such as fluorine, chlorine and hybrids of these elements, such as the oxyfluorides, the oxychlorides, etc. The superscripts in formula (1) indicate the valences of the respective elements, and the subscripts indicate the number of moles of the material in a mole of the compound, or in terms of the unit cell, the number of atoms of the element, on the average, in the unit cell. The subscripts can be integer or fractional. That is, formula (1) includes the cases where the unit cell may vary throughout the material; e.g. in SrBi₂(Ta_{0.75}N_{0.25})₂O₉, on the average, 75% of the B-sites are occupied by a tantalum atom and 25% of the B-sites are occupied by a niobium atom. If there is only one A-site element in the compound, then it is represented by the “A1” element and w2 . . . wj all equal zero. If there is only one B-site element in the compound, then it is represented by the “B1” element, and y2 . . . yl all equal zero, and similarly for the superlattice generator elements. The usual case is that there is one A-site element, one superlattice generator element, and one or two B-site elements, although formula (1) is written in the more general form since the invention is intended to include the cases where either of the sites and the superlattice generator can have multiple elements. The value of z is found from the equation:

(a1w1+ a2w2 . . . +ajwj)+ (s1x1+ s2x2 . . . +skxk)+ (b1y1+b2y2 . . . + b1y1)= 2z. (2)

Formula (1) includes all three of the Smolenskii type compounds discussed in U.S. Pat. No. 5,519,234 issued May 21, 1996, which is hereby incorporated by reference as though fully incorporated herein. The layered superlattice materials do not include every material that can be fit into Formula (1), but only those which spontaneously form themselves into crystalline structures with distinct alternating layers.

The terms “layered superlattice material”, “layered superlattice compound”, and “layered superlattice material compound” are used virtually interchangeably in this specification and their meaning is clear from the context.

It is known in the art that ferroelectric nonvolatile memories possessing good electronic properties are fabricated by forming a thin film of strontium bismuth tantalate material comprising chemical elements in proportions approximately represented by the stoichiometric formula SrBi₂Ta₂O₉. Based on the Watanabe et al. U.S. Pat. No. 5,434,102 patent and related work, the precursor for making layered superlattice materials currently preferred by those skilled in the art has the stoichiometric formula SrBi_{2.18}Ta_{1.44}Nb_{0.56}O₉.

2. Detailed Description of the Fabrication Process

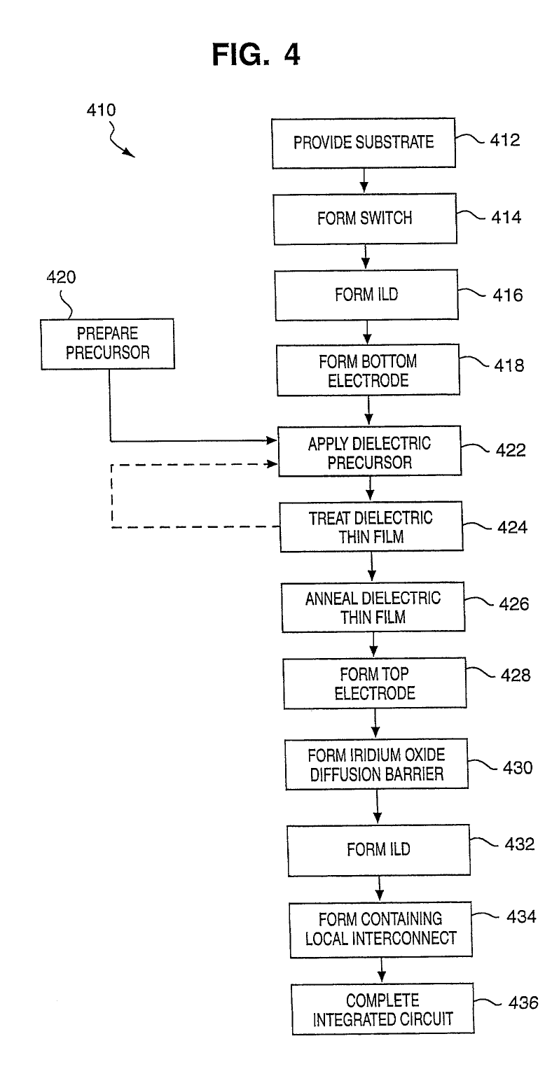

The diagram of FIG. 4 is a flow sheet of the fabrication process 410 to make a ferroelectric memory 100 incorporating a diffusion barrier layer 130 in a preferred embodiment of the invention, according to FIG. 1. The ferroelectric memory 100 is preferably formed on a conventional wafer that may be silicon, gallium arsenide or other semiconductor, or an insulator, such as glass or magnesium oxide (MgO). In step 412, a semiconductor substrate 102 (FIG. 1) is provided on which a switch 114 is formed in step 414. The switch is typically a MOSFET. In step 416, a first interlayer dielectric (ILD) layer 116 is formed to separate the switching element from the ferroelectric element to be formed. In step 418, a bottom electrode layer 122 is formed. Preferably, the electrode layer 122 is made of platinum and is sputter-deposited to form a layer with a thickness of about 200 nm. In the preferred method, an adhesion layer 118 made of titanium or titanium nitride of about 20 nm would be formed in this step, preferably by sputtering, prior to depositing the electrode. In step 420, chemical precursors of the desired thin film of layered superlattice material are prepared. Preferably, the precursors contain compounds for forming ferroelectric layered superlattice materials having the stoichiometric formula SrBi_{2.18}Ta_{1.44}Nb_{0.56}O₉, The precursor is applied to the bottom electrode layer 122 in step 422. A MOCVD method is the most preferred method to form the dielectric thin film. The precursor also can be applied using a liquid deposition technique, such as a spin-coating or a misted deposition method as described in U.S. Pat. No. 5,456,945. Usually, a final precursor solution is prepared from commercially available solutions containing the chemical precursor compounds. Preferably, the concentrations of the various precursors supplied in the commercial solutions are adjusted in step 420 to accommodate particular manufacturing or operating conditions. For example, the stoichiometric amounts of the various elements in a typical commercial solution for a layered superlattice thin film might be SrBi_{2.18}Ta_{1.44}Nb_{0.5}O₉. It is often desirable, however, to add extra niobium or bismuth to this solution to generate extra oxides that will protect the ferroelectric compounds from hydrogen degradation during reducing conditions. The application step 422 is preferably followed by a treatment process 424, which typically includes drying and heating at elevated temperatures, such as in a hot-plate bake and a rapid thermal process (RTP) anneal; treatment step 424 may include treatment with ultraviolet radiation during or after the application step 422. Steps 422 and 424 may be repeated (indicated by the dashed line in FIG. 4) as necessary to form a film of the desired thickness. For example, in a typical spin-on procedure, a coat of the precursor might be applied, dried and RTP-treated. Then another precursor coat might be applied, dried and RTP-treated. Typically, in step 426 the coating is then annealed in oxygen to form the dielectric thin film 124 with desired properties. Following steps 422-426, the top electrode layer 126 is formed in step 428. Preferably, top electrode layer 126 is made of platinum and is sputter-deposited to form a layer with a thickness of about 200 nm. In step 430, diffusion barrier layer 130 is deposited. Diffusion barrier layer 130 comprises iridium oxide, IrO₂. Preferably, diffusion barrier layer 130 is deposited on top electrode layer 126 by a sputtering process. Preferably, it has a thickness of about 20-50 nm.

Patterning steps via processes such as ion milling and ashing, as known in the art, are also included as appropriate in the fabrication of memory cell 100. For example, step 418 may include such a patterning process, and another patterning process may follow step 426. Preferably, however, a plurality of layers are patterned in a single patterning step. Barrier layer formation step 430 preferably includes a patterning and etching process in which the stacked layers 118, 122, 124, 126 and 130 are patterned to form ferroelectric memory capacitor 128, covered by self-aligning diffusion barrier layer 130. Preferably, only two etching processes are required to complete the patterning processes of step 430. Preferably, a conventional ion milling process is used. A second ILD layer 136 is deposited in step 432 to cover ILD 116 and memory capacitor 128, including diffusion barrier layer 130. In step 434, wiring holes 142, 144, 146, and 148 are made through the ILD layers 116 and 136, as depicted in FIG. 1, to the switch 114 (typically to the source and drain regions of a MOSFET), to the bottom electrode 122, and to diffusion barrier layer 130, respectively. Preferably, a standard ion milling process forms wiring holes 142, 144, 146, and 148. Thereafter, metallized wiring layers (“LI”) 152, 154, 156, and 158 are formed, as depicted in FIG. 1, preferably using a sputtering process. LI 152, 154, 156 and 158 are patterned and etched using conventional processes, and then annealed at about 450° C.

The circuit is completed in step 336, which typically includes deposition of a passivation layer.

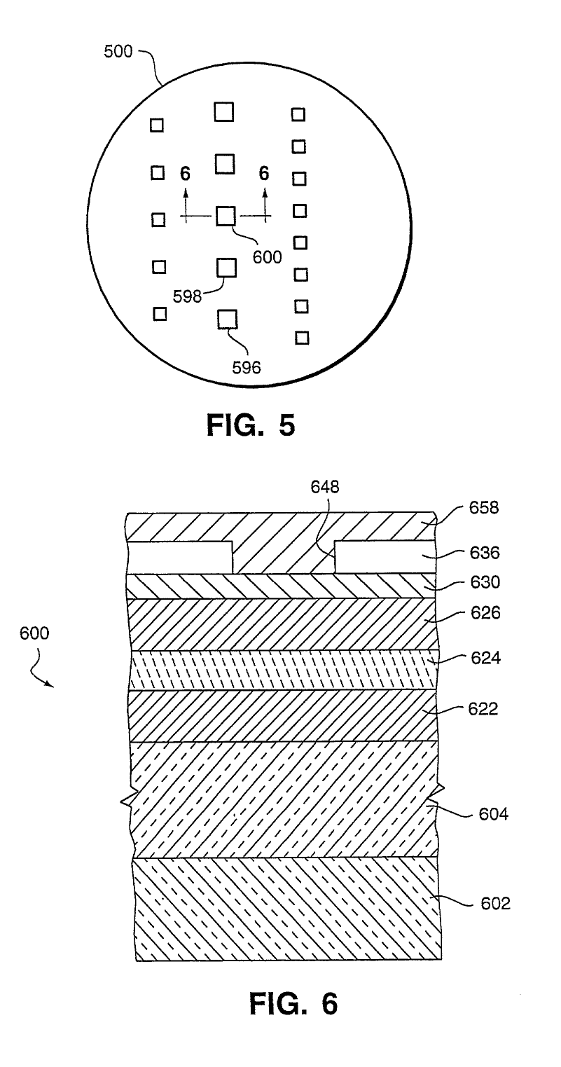

FIG. 5 is a top view of an exemplary wafer on which thin film capacitors 596, 598 and 600 fabricated on wafer 500 in accordance with the invention are shown greatly enlarged. FIG. 6 is a portion of a cross-section of FIG. 5 taken through the lines 6-6, illustrating a thin film capacitor device fabricated in accordance with the invention. A silicon dioxide layer 604 is formed on a silicon crystal substrate 602. Then bottom electrode 622 made of platinum is sputter-deposited on silicon dioxide layer 604. Layer 624 is a thin film of ferroelectric layered superlattice material, and layer 626 represents the top electrode made of platinum. A diffusion barrier layer 630 comprising iridium oxide is located on top electrode 626, and an ILD 636 is formed on layer 630. A wiring hole 648 is etched in layer 636, and titanium-containing LI metallization layer 658 is formed to fill wiring hole 648 and make contact with electrically conductive diffusion barrier layer 630.

### EXAMPLE 1

The electronic properties of strontium bismuth tantalate capacitors were measured to study the efficacy of iridium oxide (IrO₂) as a barrier layer in protecting against diffusion of titanium from a titanium-containing local interconnect into the ferroelectric thin film.

The capacitors were fabricated from a strontium bismuth tantalate (SBT) precursor solution commercially available from the Kojundo Chemical Corporation. The solution contained amounts of chemical precursors corresponding to the stoichiometric formula SrBi₂Ta₂O₉. The 0.2 mol/l precursor commercial solution contained: bismuth 2-ethylhexanoate, strontium 2-ethylhexanoate, and tantalum 2-ethylhexanoate. Ferroelectric capacitors containing the layered superlattice compound were formed from the precursor solution in general accordance with the method described in Watanabe, U.S. Pat. No. 5,434,102, which is hereby incorporated by reference as if wholly contained herein.

A series of p-type 100 Si wafer substrates 602 were oxidized to form a layer of silicon dioxide 604. These were dehydrated 30 minutes at 180° C. in a low vacuum. Then a bottom platinum electrode 622 with a thickness of 200 nm was sputter-deposited on silicon dioxide layer 604, annealed 30 minutes in O₂ at 650° C., and dehydrated as above. The 0.2 molar SBT-precursor solution was diluted with n-butyl acetate to 0.12 molar concentration prior to deposition. A spincoat of the 0.12 molar solution of the SBT-precursor was deposited on the bottom electrode 622 at 1500 rpm for 30 seconds. This was dehydrated by a hot-plate bake at 160° C. for one minute, and at 260° C. for four minutes; then a RTP was conducted in oxygen at 725° C. for 30 seconds, with a ramping rate of 100° C. per second. The sequence of the spincoat, baking and RTP steps was repeated. These steps formed a ferroelectric thin film 624 having a thickness of 180-190 nm. The wafer and deposited layers were given a so-called ferro-anneal for 60 minutes at 800° C. in O₂ gas, with 10 minutes push/pull. Platinum was sputter-deposited to make a top electrode layer 626 with a thickness of 200 nm. On certain experimental wafers, a diffusion barrier layer 630 according to the invention was formed. An iridium target was sputtered using an argon atmosphere to form a layer of iridium with a thickness of 100 nm. In the ensuing oxygen anneal steps described below, the deposited iridium was oxidized to form a layer of iridium oxide in accordance with the invention. The layers 622, 624, and 626, as well as 630 when present, were patterned and etched using conventional methods to form capacitors, and then ashing was performed, followed by a first recovery anneal for 30 minutes at 800° C. in O₂ gas flowing at 6 liters per minute, with 10 minutes push/pull. An ILD layer 636 was deposited on the wafer using a spin-on method. A layer of spin-on-glass (“SOG”) was applied using 3000 rpm for 30 seconds. This was hot-plate baked at 160° C. for five minutes, and at 260° C. for five minutes, followed by an SOG anneal at 800° C. for five minutes in oxygen gas flowing at 5 liters per minute, with five minutes push/pull. The sequence of spin-on, bake and anneal steps was repeated twice. The ILD 636 was patterned and etched using conventional methods, then a second recovery anneal was performed at 800° C. for five minutes in oxygen gas flowing at 5 liters per minute, with 10 minutes push/pull.

Finally, LI (“local interconnect”) layer 658 comprising principally platinum was formed either on top electrode layer 626, or on diffusion barrier layer 630, if present. On certain wafers, a titanium adhesion sublayer was deposited prior to depositing the platinum. The titanium adhesion sublayer was deposited by sputtering a titanium target at 8 mTorr pressure in an argon atmosphere. The platinum was deposited by sputtering a platinum target. Upon annealing, the titanium adhesion sublayer, if used, diffuses into the adjacent layers and is, therefore, not discernable as a distinct layer. After patterning and etching the LI layer 658, test anneals and measurements of electronic properties of the resulting capacitors were performed. These experimental capacitors had a surface area of about 900 μm².

Thus, three types of test capacitors were formed and studied. In the first type, only platinum was deposited to form LI layer 658, so the capacitor contained no titanium in LI layer 658. In the second type, LI layer 658 was formed by depositing a titanium adhesion sublayer and then platinum on the platinum top electrode layer 626. Thus, titanium was present at the interface of top electrode layer 626 and LI layer 658. The first and second types did not have an inventive diffusion barrier layer. In the third type, diffusion barrier layer 630 comprising iridium oxide in accordance with the invention was formed on platinum top electrode layer 626, and then LI layer 658 comprising titanium and platinum was formed.

The surface area of contact between LI layer 658 and the underlying layer, either top electrode layer 626 or diffusion barrier layer 630, was varied. In one set of the three types of capacitor, the area of contact was about 90% of the surface area of the top electrode 626 of the capacitor. In a second set of the three types of capacitor, the area of contact was about 10% of the top electrode. It should be noted that the surface area of the experimental capacitors, 900 μm², was relatively large. In actual commercial integrated circuits, the surface areas are often only 100 μm². This means that an experimental LI layer contacting about 10% of the underlying experimental capacitor surface would contact virtually 100% of the top surface of a commercial capacitor having a surface area of 100 μm², thereby corresponding to a maximum surface area of potential titanium diffusion.

From hysteresis curves measured at 3 volts, the remnant polarization of the capacitors was calculated as the 2Pr-value, in units of μC/cm². Initial measurements were made after the LI layer 658 was deposited and etched, before annealing. Then the capacitors were annealed at 400° C. for 30 minutes in oxygen-gas flowing at 5 liters per minute, with 10 minutes push/pull, and the 2Pr-values were measured again. The sequence of annealing and measuring was repeated at annealing temperatures of 450° C. and 500° C.

The results of the experimental measurements are shown in the graph of FIG. 7. For each set of fabrication conditions, the measurements were conducted usually on five capacitors and averaged. Thus, each point plotted on the graph of FIG. 7 represents the average value from measurements of five test capacitors. In FIG. 7, the average 2Pr-value, in units of μC/cm², is plotted versus annealing conditions. The experimental average values from Capacitors 1 are represented by the solid circles connected by the solid line. Capacitors 1 contained no diffusion barrier, and their LI layer contacted about 90% of the top electrode surface area of Capacitors 1. Capacitors 2, represented by upright triangles connected by a dotted line, had no diffusion barrier, but their LI layer covering 90% of their top electrode surface did include titanium. Capacitors 3, represented by solid squares connected by a dot-dash line, were covered by an iridium-oxide diffusion barrier, and their LI layer, covering 90% of their top electrode surface, included titanium. Capacitors 4, represented by solid diamonds connected by short dashes, had no diffusion barrier and no titanium in their LI, and the LI covered only 10% of their top electrode surface. Capacitors 5, represented by solid triangles connected by long dashes, had no diffusion barrier, but contained titanium in their LI, and the LI covered 10% of their top electrode surface. Capacitors 6, represented by empty circles connected by a dot-dash line, had both an iridium-oxide diffusion barrier and titanium in their LI, and the LI covered 10% of their top electrode surface.

The data plotted in FIG. 6 show that, before annealing of the LI layer, the average 2Pr-value in the various capacitors was in the range of about 12.5 to 14.5 μC/cm². After annealing at 400° C., however, the 2Pr-value in Capacitors 2, having no diffusion barrier, but having titanium in the LI layer, and having 90% of their surface area covered by the LI, dropped precipitously to about 8.5 μC/cm². This was presumably caused by diffusion of titanium through the platinum into the ferroelectric material. In contrast, the 2Pr-value of Capacitors 1, which had no titanium, stayed about the same after annealing at 400° C., as did the 2Pr-value of Capacitors 3, which contained titanium in their LI, but which were protected by the iridium-oxide diffusion barrier, in accordance with the invention. The 2Pr-values in Capacitors 4 and 6 remained essentially unchanged after annealing at 400° C. The 2Pr-value in Capacitors 5 actually increased after annealing at 400° C., even though Capacitors 5 contained titanium in their LI and were not protected by an iridium-oxide layer. This can be explained by the fact that only 10% of the total top electrode surface area of Capacitors 5 was in contact with the titanium-containing LI, so the relative amount of diffusing titanium was insignificant, and the improvement in electrical contact between LI and capacitor caused by annealing was the dominant effect.

After annealing at 450° C. and 500° C., the average 2Pr-value in Capacitors 1, 3-6 was basically unchanged. In Capacitors 2, however, the polarizability after additional annealing was so low that the 2Pr-value could not be measured. The experimental results depicted in FIG. 7 show that the iridium oxide diffusion barrier of the invention effectively protects layered superlattice material by inhibiting diffusion of chemical species from a LI layer into the layered superlattice material.

There has been described structures and fabrication methods of a novel composition of diffusion barrier layer for protecting layered superlattice materials in integrated circuits. The diffusion barrier layer of the invention protects layered superlattice material by inhibiting diffusion of chemical species from LI layers. In particular, there has been described a composition, a structure and a method for fabricating an integrated circuit containing layered superlattice material in a memory capacitor that permits the use of standard LI layers and still results in devices with good electronic properties. It should be understood that the particular embodiments shown in the drawings and described within this specification are for purposes of example and should not be construed to limit the invention which will be described in the claims below. Further, it is evident that those skilled in the art may now make numerous uses and modifications of the specific embodiments described, without departing from the inventive concepts. It is also evident that the steps recited may in some instances be performed in a different order; or equivalent structures and processes may be substituted for the various structures and processes described. Consequently, the invention is to be construed as embracing each and every novel feature and novel combination of features present in and/or possessed by the disclosed compositions, and their use in fabrication processes, electronic devices, and electronic device manufacturing methods described.

We claim:

1. An integrated circuit comprising:
a thin film of layered superlattice material;
a local interconnect; and
a diffusion barrier layer, said diffusion barrier layer comprising iridium oxide and located between said thin film of layered superlattice material and said local interconnect to inhibit diffusion of a chemical species from said local interconnect towards said thin film of layered superlattice material.

2. An integrated circuit as in claim 1, wherein said local interconnect is a metallized wiring layer, and said thin film of layered superlattice material is a dielectric thin film in a memory capacitor.

3. An integrated circuit as in claim 2, further comprising a top electrode layer located on said dielectric thin film, and wherein said diffusion barrier layer is located above said top electrode layer, and said metallized wiring layer is located above said diffusion barrier layer.

4. An integrated circuit as in claim 2, wherein said chemical species is a metal.

5. An integrated circuit as in claim 4, wherein said metal is selected from the group consisting of titanium, titanium nitride, aluminum, copper and tungsten.

6. An integrated circuit as in claim 2, wherein said dielectric thin film comprises a nonferroelectric, high-dielectric constant material.

7. An integrated circuit as in claim 2, wherein said dielectric thin film comprises ferroelectric material.

8. An integrated circuit as in claim 7, wherein said ferroelectric material comprises strontium, bismuth and tantalum.

9. An integrated circuit as in claim 7, wherein said ferroelectric material comprises strontium, bismuth and tantalum in relative molar proportions corresponding to a stoichiometric formula SrBi₂Ta₂O₉.

10. An integrated circuit as in claim 7, wherein said ferroelectric material comprises strontium, bismuth, tantalum and niobium.

11. An integrated circuit as in claim 7, wherein said ferroelectric material comprises strontium, bismuth, tantalum and niobium in relative molar proportions corresponding to a stoichiometric formula SrBi_{2.18}Ta_{1.44}Nb_{0.56}O₉.

12. An integrated circuit as in claim 3, wherein said diffusion barrier layer is in direct contact with said metallized wiring layer.

13. An integrated circuit as in claim 1, wherein said local interconnect is an electrically conductive plug, said thin film of layered superlattice material is a dielectric thin film in a memory capacitor, and said memory capacitor is above said electrically conductive plug.

14. An integrated circuit as in claim 13, wherein said memory capacitor comprises a bottom electrode layer, said dielectric thin film is located on said bottom electrode layer, said diffusion barrier layer is above said electrically conductive plug, and said bottom electrode layer is above said diffusion barrier layer.

15. An integrated circuit as in claim 13, wherein said diffusion barrier layer is in direct contact with said electrically conductive plug.

16. An integrated circuit as in claim 13, wherein said chemical species is tungsten.

17. An integrated circuit as in claim 13, wherein said chemical species is silicon.

18. An integrated circuit as in claim 13, wherein said dielectric thin film comprises nonferroelectric, high-dielectric constant material.

19. An integrated circuit as in claim 13, wherein said dielectric thin film comprises ferroelectric material.

20. An integrated circuit as in claim 19, wherein said ferroelectric material comprises strontium, bismuth and tantalum.

21. An integrated circuit as in claim 19, wherein said ferroelectric material comprises strontium, bismuth and tantalum in relative molar proportions corresponding to a stoichiometric formula SrBi₂Ta₂O₉.

22. An integrated circuit as in claim 19, wherein said ferroelectric material comprises strontium, bismuth, tantalum and niobium.

23. An integrated circuit as in claim 19, wherein said ferroelectric material comprises strontium, bismuth, tantalum and niobium in relative molar proportions corresponding to a stoichiometric formula SrBi_{2.18}Ta_{1.44}Nb_{0.56}O₉.

24. A method of forming an integrated circuit comprising steps of:
forming a thin film of layered superlattice material;
forming a local interconnect; and
forming a diffusion barrier layer, said diffusion barrier layer comprising iridium oxide and located between said thin film of layered superlattice material and said local interconnect to inhibit diffusion of a chemical species from said local interconnect towards said thin film of layered superlattice material.

25. A method of forming an integrated circuit as in claim 24, wherein said local interconnect is a metallized wiring layer, and said thin film of layered superlattice material is a dielectric thin film in a memory capacitor.

26. A method of forming an integrated circuit as in claim 25, further comprising a step of forming a top electrode layer on said dielectric thin film, wherein said diffusion barrier layer is formed above said top electrode layer, and said metallized wiring layer is formed above said diffusion barrier layer.

27. An integrated circuit as in claim 26, wherein said diffusion barrier layer is in direct contact with said metallized wiring layer.

28. A method of forming an integrated circuit as in claim 24, wherein said local interconnect is an electrically conductive plug, and said thin film of layered superlattice material is a dielectric thin film in a memory capacitor.

29. A method of forming an integrated circuit as in claim 27, wherein said diffusion barrier layer is formed above said electrically conductive plug, and further comprising a step of forming a bottom electrode layer above said diffusion barrier layer, and wherein said dielectric thin film is formed on said bottom electrode layer.

30. An integrated circuit as in claim 29, wherein said diffusion barrier layer is in direct contact with said electrically conductive plug.
